(19) United States
(12) Patent Application Publication
(10) Pub. No.: US 2013/0284256 A1
(43) Pub. Date: Oct. 31, 2013

(54) LEAD-FREE CONDUCTIVE PASTE COMPOSITION AND SEMICONDUCTOR DEVICES MADE THEREWITH

(71) Applicant: E I DU PONT DE NEMOURS AND COMPANY, (US)

(72) Inventors: BRIAN J. LAUGHLIN, APEX, NC (US); CARMINE TORARDI, WILMINGTON, DE (US); PAUL DOUGLAS VERNOOY, HOCKESSIN, DE (US)

(73) Assignee: E I DU PONT DE NEMOURS AND COMPANY, Wilmington, DE (US)

(21) Appl. No.: 13/659,314

(22) Filed: Oct. 24, 2012

Related U.S. Application Data
(63) Continuation-in-part of application No. 12/756,423, filed on Apr. 8, 2010, now abandoned.
(60) Provisional application No. 61/167,892, filed on Apr. 9, 2009.

(51) Int. Cl. H01L 31/0224; H01L 21/283; H01L 29/45

(52) U.S. Cl. CPC H01L 31/022425; H01L 29/456; H01L 21/283
USPC 136/256; 252/514; 438/661; 257/741

(57) ABSTRACT

A lead-free conductive paste composition contains a source of an electrically conductive metal, a fusible material, an optional additive, and an organic vehicle. An article such as a high-efficiency photovoltaic cell is formed by a process of deposition of the lead-free paste composition on a semiconductor substrate (e.g., by screen printing) and firing the paste to remove the organic vehicle and sinter the metal and fusible material.

### CROSS-REFERENCE TO RELATED APPLICATIONS

This application is a continuation-in-part of U.S. patent application Ser. No. 12/756,423, filed Apr. 8, 2010, which, in turn, claims benefit of U.S. Provisional Patent Application Ser. No. 61/167,892, filed Apr. 9, 2009. Each of these applications is incorporated herein in its entirety for all purposes by reference thereto.

### FIELD OF THE INVENTION

Embodiments of the invention relate to a silicon semiconductor device, and a conductive thick-film composition containing fusible material for use in a solar cell device.

### TECHNICAL BACKGROUND OF THE INVENTION

A conventional solar cell structure with a p-type base has a negative electrode that may be on the front side (also termed sun side or illuminated side) of the cell and a positive electrode that may be on the opposite side. Radiation of an appropriate wavelength falling on a p-n junction of a semiconductor body serves as a source of external energy to generate hole-electron pairs in that body. Because of the potential difference which exists at a p-n junction, holes and electrons move across the junction in opposite directions and thereby give rise to flow of an electric current that is capable of delivering power to an external circuit. Solar cells are commonly in the form of a silicon wafer that has been metalized, i.e., provided with metal contacts that are electrically conductive.

There is a need for compositions, structures (for example, semiconductor, solar cell, or photodiode structures), and semiconductor devices (for example, semiconductor, solar cell, or photodiode devices) which have improved electrical performance, and methods of making them.

### SUMMARY OF THE INVENTION

An embodiment of the invention relates to composition comprising:

(a) a source of electrically conductive metal;

(b) a fusible material comprising:
60-90 wt. % Bi₂O₃,
0-15 wt. % Al₂O₃,
1-26 wt. % SiO₂, and
0-7 wt. % B₂O₃,
wherein the weight percentages are based on the total fusible material, and wherein some or all of at least one of the oxides is optionally replaced by a fluoride of the same cation in an amount such that the fusible material comprises at most 5 wt. % of fluorine, based on the total fusible material; and

(c) an organic vehicle, and

wherein the composition is lead-free and zinc-free.

Another aspect provides a process for forming an electrically conductive structure on a substrate comprising:
(a) providing a substrate having a first major surface;
(b) applying a composition onto a preselected portion of the first major surface, wherein the composition comprises:
   i. a source of electrically conductive metal;
   ii. a fusible material comprising:
      60-90 wt. % Bi₂O₃,
      0-15 wt. % Al₂O₃,
      1-26 wt. % SiO₂, and
      0-7 wt. % B₂O₃,
      wherein the weight percentages are based on the total fusible material, and wherein some or all of at least one of the oxides is optionally replaced by a fluoride of the same cation in an amount such that the fusible material comprises at most 5 wt. % of fluorine, based on the total fusible material; and
   iii. an organic medium,
   wherein the composition is lead-free and zinc-free; and
(c) firing the substrate and composition thereon, whereby the electrically conductive structure is formed on the substrate.

Further aspects provide a semiconductor device comprising an electrically conductive structure, wherein the electrically conductive structure, prior to firing, comprises the foregoing composition, and a photovoltaic cell comprising such a semiconductor device.

### DETAILED DESCRIPTION OF THE INVENTION

As used herein, the term “thick-film composition” refers to a composition which, upon firing on a substrate, has a thickness of 1 to 100 microns. The thick-film compositions herein contain a conductive material, a fusible material, and organic vehicle. The thick-film composition may include additional components. As used herein, the additional components are termed “additives”.

The present thick-film composition, which also may be termed a “paste composition,” may be used to form conductive structures, e.g., by printing the composition onto a substrate and firing the deposited material.

Conductors thus formed are often denominated as “thick-film” conductors, since they are ordinarily substantially thicker than traces formed by atomistic processes, such as those used in fabricating integrated circuits. For example, thick-film conductors may have a thickness after firing of about 1 to 100 μm. Consequently, paste compositions that in their processed form provide conductivity and are suitably applied using printing processes are often called “thick-film pastes” or “conductive inks.”

The compositions described herein include one or more electrically functional materials and one or more fusible materials dispersed in an organic vehicle. These compositions may be thick-film compositions. The compositions may also include one or more additive(s). Exemplary additives may include metals, metal oxides, or any compounds that can generate these metal oxides during firing.

In an embodiment, the electrically functional powders may be conductive powders. In an embodiment, the composition(s), for example conductive compositions, may be used in a semiconductor device. In an aspect of this embodiment, the semiconductor device may be a solar cell or a photodiode. In a further aspect of this embodiment, the semiconductor device may be one of a broad range of semiconductor devices.

### Fusible Material

The present composition includes a fusible material. The term “fusible,” as used herein, refers to the ability of a material to become fluid upon heating, such as the heating employed in a firing operation. In some embodiments, the fusible material of the present composition is composed of one or more fusible subcomponents.

For example, the fusible material may comprise a glass material, or a mixture of two or more glass materials. Glass material in the form of a fine powder, e.g., as formed by a comminution operation, is often termed “frit” and is readily incorporated in the present composition. In an exemplary embodiment, certain frits useful as the fusible material in the present composition are listed in Tables I and V below.

It is also contemplated that some or all of the fusible material may be composed of material that exhibits some degree of crystallinity. For example, in some embodiments, a plurality of oxides are melted together and quenched as set forth herein, resulting in a material that is partially amorphous and partially crystalline. As would be recognized by a skilled person, such a material would produce an X-ray diffraction pattern having narrow, crystalline peaks superimposed on a pattern of broad amorphous peaks. Alternatively, one or more constituents, or even substantially all of the fusible material, may be predominantly or even substantially fully crystalline. In an embodiment, crystalline material useful in the fusible material of the present composition may have a melting point of at most 800° C.

Fusible materials are described herein as including percentages of certain components (also termed the elemental constituency). Specifically, the percentages are the percentages of the components used in the starting material that may subsequently be processed as described herein to form a fusible material. Such nomenclature is conventional to one of skill in the art. In other words, the fusible material contains certain components, and the percentages of those components are expressed as a percentage of the corresponding oxide form. As recognized by one of skill in the art in glass chemistry, a certain portion of volatile species may be released during the process of making the fusible material. Examples of volatile species include oxygen, water, and carbon dioxide.

The skilled person would also recognize that a fusible material composition specified in this manner may alternatively be prepared by supplying the required anions and cations in requisite amounts from different components that, when mixed, yield the same overall composition. For example, in various embodiments, phosphorus could be supplied either from P₂O₅ or alternatively from a phosphate of one of the cations of the composition.

Although oxygen is typically the predominant anion in the fusible material of the present composition, some portion of the oxygen may be replaced by fluorine to alter certain properties, such as chemical, thermal, or rheological properties of the material that affect firing. One of ordinary skill would recognize that embodiments wherein the composition contains fluorine can be prepared using fluoride anions supplied from a fluoride-containing compound, such as a simple fluoride or an oxyfluoride. For example, the desired fluorine content can be supplied by replacing some or all of an oxide nominally specified in the composition with a corresponding fluoride-containing compound of the same cation. For example, some or all of the Li₂O, Na₂O, or Bi₂O₃ nominally included could be replaced with the amount of LiF, NaF, or BiF₃ needed to attain the desired level of F content. Of course, the requisite amount of F can be derived by replacing the oxides of more than one of the composition's cations if desired. Other fluoride sources could also be used, including sources such as ammonium fluoride that would decompose during the heating in a typical melting operation to leave behind residual fluoride anions. Other fluorides useful include, but are not limited to, BiF₃, AIF₃, NaF, LiF, KF, CsF, ZrF₄, and/or TiF₄.

It is known to those skilled in the art that a fusible material, such as one prepared by a melting technique as described herein, may be characterized by known analytical methods that include, but are not limited to: Inductively Coupled Plasma-Emission Spectroscopy (ICP-ES), Inductively Coupled Plasma-Atomic Emission Spectroscopy (ICP-AES), and the like. In addition, the following exemplary techniques may be used: X-Ray Fluorescence spectroscopy (XRF), Nuclear Magnetic Resonance spectroscopy (NMR), Electron Paramagnetic Resonance spectroscopy (EPR), Mössbauer spectroscopy, electron microprobe Energy Dispersive Spectroscopy (EDS), electron microprobe Wavelength Dispersive Spectroscopy (WDS), and Cathodoluminescence (CL). A skilled person could calculate percentages of starting components that could be processed to yield a particular fusible material, based on results obtained with such analytical methods.

In an embodiment, the amount of fusible material in the total composition is in the range of 0.5 to 10 wt. %, or 1 to 6 wt. %, or 2 to 5 wt. %, based on the total composition.

The fusible materials described herein, including the glass compositions listed in Table I, are not limiting; it is contemplated that one of ordinary skill in the art of glass chemistry could make minor substitutions of additional ingredients and not substantially change the desired properties of the fusible material. For example, substitutions of glass formers such as 0-3 wt. % P₂O₅, GeO₂, or V₂O₅ may be used either individually or in combination to achieve similar performance. For example, one or more intermediate oxides, such as HfO₂, Ta₂O₅, Nb₂O₅, CeO₂, and SnO₂ may be substituted for other intermediate oxides (i.e., Al₂O₃, ZrO₂, or TiO₂) present in a glass composition.

An aspect relates to fusible material compositions including one or more fluorine-containing components, including but not limited to: salts of fluorine, fluorides, metal oxyfluoride compounds, and the like. Such fluorine-containing components include, but are not limited to BiF₃, AlF₃, NaF, LiF, KF, CsF, ZrF₄, and/or TiF₄.

Exemplary methods for producing the frits and other fusible materials described herein include those used in conventional glass manufacture. Ingredients are weighed, then mixed in the desired proportions, and heated in a furnace to form a melt, e.g., in a platinum alloy crucible. One skilled in the art of producing fusible materials, including glass compositions, could employ oxides as raw materials as well as fluoride or oxyfluoride salts. Alternatively, salts, such as nitrates, nitrites, carbonates, or hydrates, which decompose into oxide, fluorides, or oxyfluorides at a temperature below the glass melting temperature, can be used as raw materials. As is well known in the art, heating is conducted to a peak temperature (e.g., 800° C. to 1400° C. or 1000° C. to 1200° C.) and for a time such that the melt becomes entirely liquid, homogeneous, and free of any residual decomposition products of the raw materials (e.g., 20 minutes to 2 hours). The molten material may then be quenched in any suitable way including, without limitation, passing it between counter-rotating stainless steel rollers to form 0.25 to 0.50 mm thick platelets, by pouring it onto a thick stainless steel plate, or by pouring it into water or other quench fluid. The resulting particles are then milled to form a powder. For example, the resulting glass platelets may be milled to form a powder with its 50% volume distribution (d₅₀) having a desired target (e.g. 0.8 to 2 μm). One skilled in the art of producing frit may employ alternative synthesis techniques such as but not limited to melting in non-precious-metal crucibles, melting in ceramic crucibles, water quenching, sol-gel, spray pyrolysis, or others appropriate for making powder forms of glass or similar fusible materials.

A skilled person would recognize that the choice of raw materials could unintentionally include impurities that may be incorporated into the fusible material during processing. For example, the impurities may be present in the range of hundreds to thousands of parts per million. Impurities commonly occurring in industrial materials used herein are known to one of ordinary skill.

Representative glass compositions usable in practice of the present disclosure are shown in Table I as weight percentages of the total glass composition. Unless stated otherwise, as used herein, wt. % means wt. % of glass composition only. In another embodiment, frit compositions described herein may include one or more of SiO₂, B₂O₃, P₂O₅, Al₂O₃, Bi₂O₃, BiF₃, ZrO₂, CuO, TiO₂, Na₂O, NaF, Li₂O, LiF, K₂O, and KF. In aspects of this embodiment, the

| | | | | | | |
|---|---|---|---|---|---|---|
| SiO₂ | 8 to 26 | wt. %, | 14 to 24 | wt. %, | or 20 to 22 | wt. %; |
| may be | | | | | | |
| B₂O₃ | 0 to 9 | wt. %, | 1 to 6 | wt. %, | or 3 to 4 | wt. %; |
| may be | | | | | | |
| P₂O₅ | 0 to 12 | wt. %, | 0 to 5 | wt. %, | or 1 to 4 | wt. %; |
| may be | | | | | | |
| Al₂O₃ | 0.1 to 6 | wt. %, | 0.1 to 2 | wt. %, | or 0.2 to 0.3 | wt. %; |
| may be | | | | | | |
| Bi₂O₃ | 0 to 80 | wt. %, | 40 to 75 | wt. %, | or 45 to 65 | wt. %; |
| may be | | | | | | |
| BiF₃ | 0 to 70 | wt. %, | 2 to 67 | wt. %, | or 0 to 19 | wt. %; |
| may be | | | | | | |
| ZrO₂ | 0 to 5 | wt. %, | 1 to 5 | wt. %, | or 4 to 5 | wt. %; |
| may be | | | | | | |
| CuO | 0 to 3 | wt. %, | 0.1 to 3 | wt. %, | or 2 to 3 | wt. %; |
| may be | | | | | | |
| TiO₂ | 0 to 7 | wt. %, | 0 to 4 | wt. %, | or 1 to 3 | wt. %; |
| may be | | | | | | |
| Na₂O | 0 to 5 | wt. %, | 0 to 2 | wt. %, | or 0.5 to 2 | wt. %; |
| may be | | | | | | |
| NaF | 0 to 3 | wt. %, | 1 to 3 | wt. %, | or 2 to 3 | wt. %; |
| may be | | | | | | |
| Li₂O | 0 to 3 | wt. %, | 1 to 3 | wt. %, | or 1 to 2 | wt. %; |
| may be | | | | | | |
| LiF | 0 to 3 | wt. %, | 1 to 3 | wt. %, | or 2 to 3 | wt. %; |
| may be | | | | | | |
| K₂O | 0 to 5 | wt. %, | 0 to 2 | wt. %, | or 0.5 to 2 | wt. %; |
| may be or | | | | | | |
| KF | 0 to 3 | wt. %, | 0 to 2 | wt. %, | or 0.5 to 2 | wt. %. |
| may be | | | | | | |

One skilled in the art of making glass would recognize that in many embodiments of glass compositions of the present disclosure, including ones set forth herein, some or all of the Na₂O or Li₂O could be replaced with equimolar amounts of K₂O, and some or all of the NaF or LiF could be replaced with equimolar amounts of KF, without materially affecting the properties of the starting glass. The skilled person would additionally recognize that some or all of one of the alkali oxides could be replaced with the corresponding alkali fluoride to create a glass with properties similar to those of the compositions listed above.

The glass compositions above can be described alternatively in wt. % of the elements of the glass composition as shown in Table II. In one embodiment the glass can be, in part:

| | | | | | | |
|---|---|---|---|---|---|---|
| Silicon | 3 to 12 | elemental wt. %, | 6 to 11 | elemental wt. %, | or 9 to 11 | elemental wt. %; |
| Aluminum | 0 to 3 | elemental wt. %, | 0 to 1 | elemental wt. %, | or 0.1 to 0.2 | elemental wt. %; |
| Zirconium | 0 to 5 | elemental wt. %, | 0 to 4 | elemental wt. %, | or 3 to 4 | elemental wt. %; |
| Boron | 0 to 3 | elemental wt. %, | 1 to 3 | elemental wt. %, | or 1 to 2 | elemental wt. %; |
| Copper | 0 to 3 | elemental wt. %, | 0 to 2 | elemental wt. %, | or 1 to 2 | elemental wt. %; |
| Titanium | 0 to 4 | elemental wt. %, | 0 to 2 | elemental wt. %, | or 1 to 2 | elemental wt. %; |
| Phosphorus | 0 to 6 | elemental wt. %, | 0 to 2 | elemental wt. %, | or 1 to 2 | elemental wt. %; |
| Lithium | 0 to 2 | elemental wt. %, | 0.1 to 1.5 | elemental wt. %, | or 0.5 to 1 | elemental wt. %; |
| Sodium | 0 to 5 | elemental wt. %, | 0.1 to 3 | elemental wt. %, | or 1 to 1.5 | elemental wt. %; |
| Potassium | 0 to 3 | elemental wt. %, | 0.1 to 3 | elemental wt. %, | or 1.5 to 2.5 | elemental wt. %; |
| Fluorine | 0 to 17 | elemental wt. %, | 3 to 17 | elemental wt. %, | or 3 to 7 | elemental wt. %; or |
| Bismuth | 45 to 75 | elemental wt. %, | 47 to 60 | elemental wt. %, | or 55 to 58 | elemental wt. %. |

In another embodiment, the frit compositions described herein may include one or more of SiO₂, B₂O₃, P₂O₅, Al₂O₃, Bi₂O₃, BiF₃, ZrO₂, CuO, Na₂O, NaF, Li₂O, LiF, K₂O, and KF. In aspects of this embodiment, the

| | | | | | | |
|---|---|---|---|---|---|---|
| SiO₂ may be | 8 to 19 | wt. %, | 12 to 19 | wt. %, | or 15 to 19 | wt. %; |
| B₂O₃ may be | 0 to 2 | wt. %, | 0.5 to 2 | wt. %, | or 1 to 2 | wt. %; |
| P₂O₅ may be | 0 to 12 | wt. %, | 0.5 to 8 | wt. %, | or 1 to 4 | wt. %; |
| Al₂O₃ may be | 1 to 6 | wt. %, | 1 to 4 | wt. %, | or 2 to 3 | wt. %; |
| Bi₂O₃ may be | 40 to 80 | wt. %, | 40 to 55 | wt. %, | or 41 to 48 | wt. %; |
| BiF₃ may be | 1 to 18 | wt. %, | 4 to 17 | wt. %, | or 12 to 16 | wt. %; |
| ZrO₂ may be | 0.1 to 2.5 | wt. %, | 0.75 to 2 | wt. %, | or 1.5 to 2 | wt. %; |
| CuO may be | 0 to 3 | wt. %, | 1 to 3 | wt. %, | or 2 to 3 | wt. %; |
| Na₂O may be | 0 to 5 | wt. %, | 0 to 3 | wt. %, | or 3 to 5 | wt. %; |
| NaF may be | 0 to 5 | wt. %, | 0 to 1 | wt. %, | or 1 to 2 | wt. %; |
| K₂O may be | 0 to 5 | wt. %, | 0 to 2 | wt. %, | or 0.25 to 0.75 | wt. %; |
| KF may be | 0 to 5 | wt. %, | 0 to 2 | wt. %, | or 1 to 3 | wt. %; |
| Li₂O may be | 0 to 5 | wt. %, | 0 to 3 | wt. %, | or 1 to 3 | wt. %; or |
| LiF may be | 0 to 5 | wt. %, | 0 to 2 | wt. %, | or 0.75 to 1.25 | wt. %. |

One skilled in the art of making glass could replace some or all of the ZrO₂ with TiO₂, HfO₂, SnO₂, Y₂O₃, or an oxide of a lanthanide group element such as La₂O₃ or CeO₂ and create a glass with properties similar to the compositions listed above. (As used herein, the term “lanthanide group” refers to the chemical elements of atomic number 57-71, or La—Lu).

The glass compositions can be described alternatively in wt. % of the elements of the glass composition as shown in Table II. In this embodiment, the glass can be, in part:

| | | | | | | |
|---|---|---|---|---|---|---|
| Silicon | 3 to 9 | elemental wt. %, | 5 to 9 | elemental wt. %, | or 7 to 9 | elemental wt. %; |
| Aluminum | 1 to 3 | elemental wt. %, | 1 to 2 | elemental wt. %, | or 1.25 to 1.5 | elemental wt. %; |
| Zirconium | 0.1 to 2 | elemental wt. %, | 0.5 to 1.5 | elemental wt. %, | or 1.25 to 1.5 | elemental wt. %; |
| Boron | 0 to 1 | elemental wt. %, | 0 to 0.6 | elemental wt. %, | or 0.45 to 0.55 | elemental wt. %; |
| Copper | 0 to 2 | elemental wt. %, | 1 to 2 | elemental wt. %, | or 1.5 to 1.75 | elemental wt. %; |
| Phosphorus | 0 to 6 | elemental wt. %, | .1 to 3 | elemental wt. %, | or 0.25 to 1.5 | elemental wt. %; |
| Lithium | 0 to 2 | elemental wt. %, | 1 to 2 | elemental wt. %, | or 1 to 1.5 | elemental wt. %; |
| Sodium | 0 to 5 | elemental wt. %, | 0 to 1 | elemental wt. %, | or 0 to 0.25 | elemental wt. %; |
| Potassium | 0 to 3 | elemental wt. %, | 1 to 2.5 | elemental wt. %, | or 1.5 to 2 | elemental wt. %; |
| Fluorine | 1 to 17 | elemental wt. %, | 1 to 6 | elemental wt. %, | or 3 to 6 | elemental wt. %; or |
| Bismuth | 45 to 75 | elemental wt. %, | 47 to 60 | elemental wt. %, | or 47 to 53 | elemental wt. %. |

In another embodiment, frit compositions described herein may include one or more of SiO₂, B₂O₃, P₂O₅, Al₂O₃, Bi₂O₃, BiF₃, ZrO₂, Na₂O, NaF, Li₂O, LiF, K₂O, and KF. In aspects of this embodiment, the

| | | | | | | |
|---|---|---|---|---|---|---|
| SiO₂ may be | 8 to 20 | wt. %, | 10 to 19 | wt. %, | or 15 to 19 | wt. %; |
| B₂O₃ may be | 0 to 2 | wt. %, | 0.5 to 2 | wt. %, | or 1 to 1.75 | wt. %; |
| P₂O₅ may be | 1 to 12 | wt. %, | 1 to 5 | wt. %, | or 1 to 4 | wt. %; |
| Al₂O₃ may be | 1 to 6 | wt. %, | 1 to 5 | wt. %, | or 2 to 3 | wt. %; |
| Bi₂O₃ may be | 40 to 80 | wt. %, | 40 to 60 | wt. %, | or 41 to 48 | wt. %; |
| BiF₃ may be | 4 to 18 | wt. %, | 10 to 16 | wt. %, | or 12 to 16 | wt. %; |
| ZrO₂ may be | 0.75 to 6 | wt. %, | 1 to 2 | wt. %, | or 2 to 3 | wt. %; |
| Na₂O may be | 0 to 5 | wt. %, | 4 to 5 | wt. %, | or 0 to 3 | wt. %; |
| NaF may be | 0 to 2 | wt. %, | 0.5 to 1.5 | wt. %, | or 0 to 0.5 | wt. %; |
| Li₂O may be | 0 to 5 | wt. %, | 0 to 3 | wt. %, | or 0.5 to 1.5 | wt. %; |
| LiF may be | 0 to 2 | wt. %, | 0.25 to 1.25 | wt. %, | or 0.75 to 1.25 | wt. %; |
| K₂O may be | 0 to 5 | wt. %, | 0.1 to 0.75 | wt. %, | or 0 to 1 | wt. %; or |
| KF may be | 0 to 3 | wt. %, | 0.1 to 2.5 | wt. %, | or 1 to 3 | wt. %. |

The glass compositions can be described alternatively in wt. % of the elements of the glass composition as shown in Table II. In this embodiment, the glass can be, in part:

| | | | | | | |
|---|---|---|---|---|---|---|
| Silicon | 3 to 9 | elemental wt. %, | 4 to 9 | elemental wt. %, | or 5 to 8 | elemental wt. %; |
| Aluminum | 1 to 3 | elemental wt. %, | 1 to 2 | elemental wt. %, | or 1.25 to 1.5 | elemental wt. %; |
| Zirconium | 0 to 2 | elemental wt. %, | 0.1 to 2 | elemental wt. %, | or 0.5 to 1.5 | elemental wt. %; |
| Boron | 0 to 1 | elemental wt. %, | 0.1 to 0.6 | elemental wt. %, | or 0.25 to 0.5 | elemental wt. %; |
| Phosphorus | 0.1 to 6 | elemental wt. %, | 0.5 to 4 | elemental wt. %, | or 1 to 2 | elemental wt. %; |
| Lithium | 0 to 2 | elemental wt. %, | 0 to 1.5 | elemental wt. %, | or 1 to 1.5 | elemental wt. %; |
| Sodium | 0 to 5 | elemental wt. %, | 0 to 4 | elemental wt. %, | or 0.1 to 0.5 | elemental wt. %; |
| Potassium | 0 to 3 | elemental wt. %, | 0 to 2 | elemental wt. %, | or 0.1 to 1.75 | elemental wt. %; |
| Fluorine | 1 to 6 | elemental wt. %, | 2 to 5 | elemental wt. %, | or 3 to 6 | elemental wt. %; |
| or | | | | | | |
| Bismuth | 45 to 75 | elemental wt. %, | 45 to 58 | elemental wt. %, | or 47 to 53 | elemental wt. %. |

In still further embodiment, frit compositions described herein may include one or more of SiO₂, B₂O₃, P₂O₅, Al₂O₃, Bi₂O₃, BiF₃, ZrO₂, Na₂O, NaF, Li₂O, LiF, K₂O, and KF. In aspects of this embodiment, the

| | | | | |
|---|---|---|---|---|
| SiO₂ may be | 11 to 19 | wt. % | or 15 to 18.25 | wt. %; |
| B₂O₃ may be | 0 to 2 | wt. % | or 1 to 2 | wt. %; |
| P₂O₅ may be | 1 to 5 | wt. % | or 1 to 3.5 | wt. %; |
| Al₂O₃ may be | 2 to 3 | wt. % | or 2.5 to 2.75 | wt. %; |
| Bi₂O₃ may be | 40 to 50 | wt. % | or 41 to 48 | wt. %; |
| BiF₃ may be | 12 to 18 | wt. % | or 12 to 16 | wt. %; |
| ZrO₂ may be | 1 to 2 | wt. % | or 1.75 to 2 | wt. %; |
| Na₂O may be | 0 to 2 | wt. % | or 0.1 to 0.5 | wt. %; |
| NaF may be | 0 to 2 | wt. % | or 0 to 1 | wt. %; |
| Li₂O may be | 0 to 3 | wt. % | or 1.5 to 2.5 | wt. %; |
| LiF may be | 0 to 2 | wt. % | or 0.75 to 1.25 | wt. %; |
| K₂O may be | 0 to 2 | wt. % | or 0.1 to 0.75 | wt. %; or |
| KF may be | 0 to 3 | wt. % | or 1.75 to 2.75 | wt. %. |

The glass compositions can be described alternatively in wt. % of the elements of the glass composition as shown in Table II. In this embodiment, the glass can be, in part,

| | | | | |
|---|---|---|---|---|
| Silicon | 5 to 9 | elemental wt. % | or 7 to 8.5 | elemental wt. %; |
| Aluminum | 1 to 2 | elemental wt. % | or 1.25 to 1.5 | elemental wt. %; |
| Zirconium | 1 to 2 | elemental wt. % | or 1.25 to 1.5 | elemental wt. %; |
| Boron | 0 to 1 | elemental wt. % | or 0 to 0.6 | elemental wt. %; |
| Phosphorus | 0 to 3 | elemental wt. % | or 0.4 to 1.5 | elemental wt. %; |
| Lithium | 0 to 2 | elemental wt. % | or 1 to 1.5 | elemental wt. %; |
| Sodium | 0 to 2 | elemental wt. % | or 0.1 to 0.25 | elemental wt. %; |
| Potassium | 0 to 3 | elemental wt. % | or 1.5 to 2.25 | elemental wt. %; |
| Fluorine | 3 to 6 | elemental wt. % | or 3.5 to 5.5 | elemental wt. %; or |
| Bismuth | 45 to 55 | elemental wt. % | or 47 to 53 | elemental wt. %. |

In another embodiment, frit compositions described herein may include one or more of SiO₂, B₂O₃, Al₂O₃, Bi₂O₃, BiF₃, ZrO₂, TiO₂, CuO, Na₂O, NaF, Li₂O, LiF. In aspects of this embodiment, the

| | | | | | | |
|---|---|---|---|---|---|---|
| SiO₂ may be | 17 to 26 | wt. %, | 19 to 24 | wt. %, | or 20 to 22 | wt. %; |
| B₂O₃ may be | 2 to 9 | wt. %, | 3 to 7 | wt. %, | or 3 to 4 | wt. %; |
| Al₂O₃ may be | 0.2 to 5 | wt. %, | 0.2 to 2.5 | wt. %, | or 0.2 to 0.3 | wt. %; |
| Bi₂O₃ may be | 0 to 65 | wt. %, | 25 to 64 | wt. %, | or 46 to 64 | wt. %; |
| BiF₃ may be | 1 to 67 | wt. %, | 2 to 43 | wt. %, | or 2 to 19 | wt. %; |
| ZrO₂ may be | 0 to 5 | wt. %, | 2 to 5 | wt. %, | or 4 to 5 | wt. %; |
| TiO₂ may be | 1 to 7 | wt. %, | 1 to 5 | wt. %, | or 1 to 3 | wt. %; |
| CuO may be | 0 to 3 | wt. % | | | or 2 to 3 | wt. %; |
| Na₂O may be | 0 to 2 | wt. % | | | or 1 to 2 | wt. %; |
| NaF may be | 0 to 3 | wt. % | | | or 2 to 3 | wt. %; |
| Li₂O may be | 0 to 2 | wt. % | | | or 1 to 2 | wt. %; or |
| LiF may be | 0 to 3 | wt. % | | | or 2 to 3 | wt. %. |

The glass compositions can be described alternatively in wt. % of the elements of the glass composition as shown in Table II. In one embodiment, the glass can be, in part,

| | | | | | | |
|---|---|---|---|---|---|---|
| Silicon | 8 to 12 | elemental wt. %, | 9 to 11 | elemental wt. %, | or 9.5 to 10.75 | elemental wt. %; |
| Aluminum | 0.1 to 3 | elemental wt. %, | 0.1 to 0.2 | elemental wt. %, | or 0.14 to 0.16 | elemental wt. %; |
| Zirconium | 0 to 4 | elemental wt. %, | 2 to 4 | elemental wt. %, | or 3 to 4 | elemental wt. %; |
| Boron | 0.5 to 3 | elemental wt. %, | 0.05 to 2 | elemental wt. %, | or 1 to 1.25 | elemental wt. %; |
| Copper | 0 to 3 | elemental wt. %, | 0 to 2.5 | elemental wt. %, | or 2 to 2.5 | elemental wt. %; |
| Titanium | 0.5 to 4 | elemental wt. %, | 1 to 4 | elemental wt. %, | or 1 to 1.5 | elemental wt. %; |
| Lithium | 0 to 1 | elemental wt. %, | 0 to 0.8 | elemental wt. %, | or 0.6 to 0.8 | elemental wt. %; |
| Sodium | 0 to 2 | elemental wt. %, | 0 to 1.5 | elemental wt. %, | or 1 to 1.5 | elemental wt. %; |
| Fluorine | 0 to 17 | elemental wt. %, | 0 to 7 | elemental wt. %, | or 3 to 7 | elemental wt. %; or |
| Bismuth | 49 to 58 | elemental wt. %, | 52 to 58 | elemental wt. %, | or 55 to 58 | elemental wt. %. |

In an embodiment, the glass can be, in part, fluorine 1 to 17 elemental wt. %, 1 to 7 elemental wt. %, or 3 to 7 elemental wt. %; or bismuth 47 to 75 elemental wt. %, 49 to 58 elemental wt. %, 52 to 58 elemental wt. %; or 55 to 58 elemental wt. %.

In a further embodiment, the frit composition(s) herein may include one or more of a third set of components: CeO₂, SnO₂, Ga₂O₃, In₂O₃, NiO, MoO₃, WO₃, Y₂O₃, La₂O₃, Nd₂O₃, FeO, HfO₂, Cr₂O₃, CdO, Nb₂O₅, Ag₂O, Sb₂O₃, and metal halides (e.g. NaCl, KBr, NaI).

A skilled person would recognize that the choice of raw materials could unintentionally include impurities that may be incorporated into the fusible material during processing. For example, the impurities may be present in the range of hundreds to thousands parts per million. Impurities commonly occurring in industrial materials used herein are known to one of ordinary skill. The presence of the impurities would not alter the properties of the fusible material, the paste composition, or the fired device. For example, a solar cell employing the present composition in its manufacture may have the efficiency described herein, even if the composition includes impurities.

The fusible material used in the present composition is believed to assist in the partial or complete penetration of the oxide or nitride insulating layer commonly present on a silicon semiconductor wafer during firing. As described herein, this at least partial penetration may facilitate the formation of an effective, mechanically robust electrical contact between a conductive structure manufactured using the present composition and the underlying silicon semiconductor of a photovoltaic device structure.

In an embodiment, the present composition (including the fusible material contained therein) is lead-free. As used in the present specification and the subjoined claims, the term “lead-free” refers to a composition to which no lead has been specifically added (either as elemental lead or as a lead-containing alloy, compound, or other like substance), and in which the amount of lead present as a trace component or impurity is 1000 parts per million (ppm) or less. In some embodiments, the amount of lead present as a trace component or impurity is less than 500 parts per million (ppm), or less than 300 ppm, or less than 100 ppm. Surprisingly and unexpectedly, photovoltaic cells exhibiting desirable electrical properties, such as high conversion efficiency, are obtained in some embodiments of the present disclosure, notwithstanding previous belief in the art that substantial amounts of lead must be included in a paste composition to attain these levels.

In still other embodiments, the present composition is zinc-free. As used in the present specification and the subjoined claims, the term “zinc-free” refers to a composition to which no zinc has been specifically added (either as elemental zinc or as a zinc-containing alloy, compound, or other like substance), either as a discrete substance or as a constituent of the electrically functional material or the fusible material, and in which the amount of zinc present as a trace component or impurity is 0.1% or less. Although zinc is frequently incorporated in glass materials, in some instances the firing of pastes containing Zn, either in the fusible material or in an additive, produces one or more zinc silicate compositions that are non-conductive and believed to be deleterious in some cases to a photovoltaic cell's functional properties. In some embodiments, photovoltaic devices in which the present lead-free composition is used to form front-side electrodes attain electrical properties that are equivalent to, or better than, those of devices made with conventional leaded pastes. Those properties can, in some cases, be obtained without the zinc-based additives heretofore believed essential for known lead-free paste compositions.

Embodiments of the present composition may also be antimony-free. As used in the present specification and the subjoined claims, the term “antimony-free” refers to a composition to which no antimony has been specifically added (either as elemental antimony or as an antimony-containing alloy, compound, or other like substance), either as a discrete substance or as a constituent of the electrically functional material or the fusible material, and in which the amount of antimony present as a trace component or impurity is 0.1% or less.

The fusible material in the present composition may optionally comprise a plurality of separate fusible subcomponents, such as one or more frits, or a substantially crystalline material with additional frit material. In an embodiment, a first fusible subcomponent is chosen for its capability to rapidly digest an insulating layer, such as that typically present on the front surface of a photovoltaic cell; further, the first fusible subcomponent may have strong corrosive power and low viscosity. A second fusible subcomponent is optionally included to slowly blend with the first fusible subcomponent to alter the chemical activity. Preferably, the composition is such that the insulating layer is partially removed but without attacking the underlying emitter diffused region, which would shunt the device, were the corrosive action to proceed unchecked. Such fusible materials may be characterized as having a viscosity sufficiently high to provide a stable manufacturing window to remove insulating layers without damage to the diffused p-n junction region of a semiconductor substrate. Alternatively, a second fusible material may react with the first fusible material to moderate the activity of the combined material, thereby limiting the interaction with the semiconductor. Ideally, the firing process results in a substantially complete removal of the insulating layer without further combination with the underlying Si substrate or the formation of substantial amounts of non-conducting or poorly conducting inclusions.

In a further aspect of this embodiment, the present composition may include electrically functional powders and fusible material dispersed in an organic vehicle. In an embodiment, these composition(s) may be used in a semiconductor device. In an aspect of this embodiment, the semiconductor device may be a solar cell or a photodiode.

### Conductive Materials

In an embodiment, the composition may include a functional phase that imparts appropriate electrically functional properties. In an embodiment the electrically functional phase may include conductive materials, such as conductive particles or powder.

For example, the present composition may include a source of an electrically conductive metal. In various embodiments, the conductive metal may be incorporated directly in the present composition as a metal powder or as a mixture of powders of two or more metals. Exemplary metals include without limitation silver, gold, copper, nickel, palladium, platinum, aluminum, and alloys (e.g., Ag—Pd and Pt—Au) and mixtures thereof. Silver is preferred for its processability and high conductivity.

In an alternative embodiment, metal is supplied by a metal oxide or salt that decomposes upon exposure to the heat of firing to form the metal. As used herein, the term “silver” is to be understood as referring to elemental silver metal, alloys of silver, and mixtures thereof, and may further include silver derived from silver oxide (Ag₂O or AgO) or silver salts such as AgCl, AgNO₃, AgOOCCH₃ (silver acetate), AgOOCF₃ (silver trifluoroacetate), Ag₃PO₄ (silver orthophosphate), or mixtures thereof. Any other form of conductive metal compatible with the other components of the composition also may be used.

Electrically conductive metal powder used in the present composition may be supplied as finely divided particles having any one or more of the following morphologies: a powder form, a flake form, a spherical form, a granular form, a nodular form, a crystalline form, other irregular forms, or mixtures thereof. The electrically conductive metal or source thereof may also be provided in a colloidal suspension, in which case the colloidal carrier would not be included in any calculation of weight percentages of the solids of which the colloidal material is part.

The particle size of the metal is not subject to any particular limitation. As used herein, “particle size” is intended to refer to “median particle size” or d₅₀, by which is meant the 50% volume distribution size. The distribution may also be characterized by d₉₀, meaning that 90% by volume of the particles are smaller than d₉₀. Volume distribution size of metal and other particulate materials discussed herein may be determined by a number of methods understood by one of skill in the art, including but not limited to laser diffraction and dispersion methods employed by a Microtrac particle size analyzer (Montgomeryville, Pa.). Dynamic light scattering, e.g., using a model LA-910 particle size analyzer available commercially from Horiba Instruments Inc. (Irvine, Calif.), may also be used. In various embodiments, the median particle size is greater than 0.2 μm and less than 10 μm, or the median particle size is greater than 0.4 μm and less than 5 μm, as measured using the Horiba LA-910 analyzer.

The electrically conductive metal may comprise any of a variety of percentages of the present composition. To attain high conductivity in a finished conductive structure, it is generally preferable to have the concentration of the electrically conductive metal be as high as possible while maintaining other required characteristics of the composition that relate to either processing or final use.

In an embodiment, the silver or other electrically conductive metal may comprise about 60% to about 90% by weight, or about 75% to about 99% by weight, or about 85 to about 99% by weight, or about 95 to about 99% by weight, of the inorganic solid components of the composition. In another embodiment, the solids portion of the composition may include about 80 to about 90 wt. % silver particles and about 1 to about 9 wt. % silver flakes. In an embodiment, the solids portion of the composition may include about 70 to about 90 wt. %. silver particles and about 1 to about 9 wt. % silver flakes. In another embodiment, the solids portion of the composition may include about 70 to about 90 wt. % silver flakes and about 1 to about 9 wt. % of colloidal silver. In a further embodiment, the solids portion of the composition may include about 60 to about 90 wt. % of silver particles or silver flakes and about 0.1 to about 20 wt. % of colloidal silver.

The electrically conductive metal used herein, particularly when in powder form, may be coated or uncoated; for example, it may be at least partially coated with a surfactant to facilitate processing. Suitable coating surfactants include, for example, stearic acid, palmitic acid, a salt of stearate, a salt of palmitate, and mixtures thereof. Other surfactants that also may be utilized include lauric acid, oleic acid, capric acid, myristic acid, linoleic acid, and mixtures thereof. Still other surfactants that also may be utilized include polyethylene oxide, polyethylene glycol, benzotriazole, poly(ethylene glycol)acetic acid, and other similar organic molecules. Suitable counter-ions for use in a coating surfactant include without limitation hydrogen, ammonium, sodium, potassium, and mixtures thereof. When the electrically conductive metal is silver, it may be coated, for example, with a phosphorus-containing compound.

In an embodiment, one or more surfactants may be included in the organic vehicle in addition to any surfactant included as a coating of conductive metal powder used in the present composition.

### Additives

Some embodiments of the present composition include an additive. In an embodiment, the additive may be a discrete material selected from one or more of the following: (a) a metal wherein said metal is selected from Bi, Gd, Ce, Zr, Ti, Mn, Sn, Ru, Co, Fe, Cu, and Cr; (b) a metal oxide of one or more of the metals selected from Bi, Gd, Ce, Zr, Ti, Mn, Sn, Ru, Co, Fe, Cu and Cr; (c) any compounds that can generate the metal oxides of (b) upon firing; and (d) mixtures thereof. Some embodiments of the present disclosure may also incorporate Zn in the form of metal, a Zn oxide, or a compound that generates a Zn oxide upon firing.

In various embodiments, any of the foregoing additives may have an average particle size in the range of 1 nanometer to 10 microns, or an average particle size of 40 nanometers to 5 microns, or an average particle size of 60 nanometers to 3 microns. In further embodiments the additive may have an average particle size of less than 100 nm; less than 90 nm; less than 80 nm; 1 nm to less than 100 nm; 1 nm to 95 nm; 1 nm to 90 nm; 1 nm to 80 nm; 7 nm to 30 nm; 1 nm to 7 nm; 35 nm to 90 nm; 35 nm to 80 nm; 65 nm to 90 nm; 60 nm to 80 nm; and ranges in between, for example.

In an embodiment, the one or more additives may be present in the composition and together comprise up to 10 wt. % of the total composition. In further embodiments, the additives may represent 2 to 10 wt. %, or 4 to 8 wt. %, or 5 to 7 wt. % of the total composition.

### Organic Vehicle

In an embodiment, the composition described herein may include an organic medium that serves as a vehicle or carrier for the inorganic solids, which may be insoluble. Typically, the composition is formulated to give it a consistency and rheology that render it suitable for printing processes, including without limitation screen printing. In an embodiment, the resulting material is relatively viscous and commonly referred to as a “paste” or an “ink.” The constituents are typically mixed using a mechanical system; they may be combined in any order, as long as they are uniformly dispersed and the final formulation has characteristics such that it can be successfully applied during end use.

A wide variety of inert viscous materials can be used as constituents of the organic vehicle, including one or more of polymers, solvents, and substances that function as surfactants, thickeners, stabilizers, and rheology modifiers. In an embodiment, the organic vehicle used in the composition may be a nonaqueous inert liquid. By “inert” is meant a material that may be removed by a firing operation without leaving any substantial residue or other adverse effect that is detrimental to final conductor line properties. Other substances, including ones known in the printing arts, may be incorporated, as long as they do not adversely affect the mechanical and electrical functioning of conductive structures formed using the composition.

The proportions of organic vehicle and inorganic components in the present composition can vary in accordance with the method of applying the paste and the kind of organic vehicle used. In an embodiment, the present composition typically contains about 76 to 95 wt. %, or 85 to 95 wt. %, of the inorganic components and about 5 to 24 wt. %, or 5 to 15 wt. %, of the organic vehicle.

The organic vehicle typically provides a medium in which the inorganic components are dispersible with a good degree of stability. In particular, the composition preferably has a stability compatible not only with the requisite manufacturing, shipping, and storage, but also with conditions encountered during deposition, e.g. by a screen printing process. Ideally, the rheological properties of the vehicle are such that it lends good application properties to the composition, including stable and uniform dispersion of solids, appropriate viscosity and thixotropy for screen printing, appropriate wettability of the paste solids and the substrate on which printing will occur, a rapid drying rate after deposition, and stable firing properties.

Substances useful in the formulation of the organic vehicle of the present composition include, without limitation, ethyl cellulose, ethylhydroxyethyl cellulose, wood rosin, mixtures of ethyl cellulose and phenolic resins, cellulose esters, cellulose acetate, cellulose acetate butyrate, polymethacrylates of lower alcohols, monobutyl ether of ethylene glycol, monoacetate ester alcohols, and terpenes such as alpha- or beta-terpineol or mixtures thereof with other solvents such as kerosene, dibutylphthalate, butyl carbitol, butyl carbitol acetate, hexylene glycol and high-boiling alcohols and alcohol esters.

In various embodiments, solvents useful in the organic vehicle include, without limitation, ester alcohols and terpenes such as alpha- or beta-terpineol or mixtures thereof with other solvents such as kerosene, dibutylphthalate, butyl carbitol, butyl carbitol acetate, hexylene glycol, and high-boiling alcohols and alcohol esters. A preferred ester alcohol is the monoisobutyrate of 2,2,4-trimethyl-1,3-pentanediol, which is available commercially from Eastman Chemical (Kingsport, Tenn.) as TEXANOL™. Some embodiments may also incorporate volatile liquids in the organic vehicle to promote rapid hardening after application on the substrate. Various combinations of these and other solvents are formulated to provide the desired viscosity and volatility.

In an embodiment, the organic vehicle may include one or more components selected from the group consisting of: bis(2-(2-butoxyethoxy)ethyl) adipate, dibasic esters, octyl epoxy tallate (DRAPEX® 4.4 from Witco Chemical), Oxocol (isotetradecanol made by Nissan Chemical) and FORALYN™ 110 (pentaerythritol ester of hydrogenated rosin from Eastman Chemical BV). The compositions may also include additional additives or components.

The dibasic ester useful in the present composition may comprise one or more dimethyl esters selected from the group consisting of dimethyl ester of adipic acid, dimethyl ester of glutaric acid, and dimethyl ester of succinic acid. Various forms of such materials containing different proportions of the dimethyl esters are available under the DBE® trade name from Invista (Wilmington, Del.). For the present composition, a preferred version is sold as DBE-3 and is said by the manufacturer to contain 85 to 95 weight percent dimethyl adipate, 5 to 15 weight percent dimethyl glutarate, and 0 to 1.0 weight percent dimethyl succinate based on total weight of dibasic ester.

Further ingredients optionally may be incorporated in the organic vehicle, such as thickeners, stabilizers, and/or other common additives known to those skilled in the art. The organic vehicle may be a solution of one or more polymers in a solvent. Additionally, effective amounts of additives, such as surfactants or wetting agents, may be a part of the organic vehicle. Such added surfactant may be included in the organic vehicle in addition to any surfactant included as a coating on the conductive metal powder of the composition. Suitable wetting agents include phosphate esters and soya lecithin. Both inorganic and organic thixotropes may also be present.

Among the commonly used organic thixotropic agents are hydrogenated castor oil and derivatives thereof, but other suitable agents may be used instead of, or in addition to, these substances. It is, of course, not always necessary to incorporate a thixotropic agent since the solvent and resin properties coupled with the shear thinning inherent in any suspension may alone be suitable in this regard.

In an embodiment, the polymer may be present in the organic vehicle in the range of 8 wt. % to 11 wt. % of the organic portion, which corresponds to about 0.1 wt. % to 5 wt. % of the total composition, for example. The composition may be adjusted to a predetermined, screen-printable viscosity with the organic vehicle.

In an embodiment, the ratio of organic vehicle composition to the inorganic components in the composition may be dependent on the method of applying the paste and the kind of organic vehicle used. In an embodiment, the dispersion may include 70-95 wt. % of inorganic components and 5-30 wt. % of organic vehicle in order to obtain good wetting.

### Application

The present composition can be applied as a paste onto a preselected portion of a major surface of the substrate in a variety of different configurations or patterns to create a conductive structure. The preselected portion may comprise any fraction of the total first major surface area, including substantially all of the area. In an embodiment, the paste is applied on a semiconductor substrate, which may be of silicon or any other semiconductor material. Useful forms of silicon substrates include, without limitation, single-crystal, multi-crystal, polycrystalline, quasi-monocrystalline, amorphous, or ribbon silicon wafers. As understood by those of ordinary skill in the photovoltaic art, the term “quasi-monocrystalline silicon” refers to ingot-cast silicon that is seeded by a monocrystalline starting material and grown under conditions that produce a material that is largely monocrystalline.

The application can be accomplished by a variety of deposition processes, including printing. Exemplary deposition processes include, without limitation, plating, extrusion or co-extrusion, dispensing from a syringe, and screen, inkjet, shaped, multiple, and ribbon printing. The composition ordinarily is applied over any insulating layer present on the first major surface of the substrate.

### Fired Thick-Film Compositions

A firing operation may be used in the present process to effect a substantially complete burnout of the organic vehicle from the deposited composition. The firing typically involves volatilization and/or pyrolysis of the organic materials. A drying operation optionally precedes the firing operation, and is carried out at a modest temperature to harden the composition by removing its most volatile organics.

The firing process is believed to remove the organic vehicle, sinter the conductive metal in the composition, and establish electrical contact between the semiconductor substrate and the fired conductive metal. Firing may be performed in an atmosphere composed of air, nitrogen, an inert gas, or an oxygen-containing mixture such as a mixed gas of oxygen and nitrogen.

In an aspect, the fusible material, conductive metal particles, and optional additives of the composition may be sintered during firing to form an electrode. The fired electrode may include components, compositions, and the like, resulting from the firing and sintering process. For example, the fired electrode may include bismuth silicates, including but not limited to Bi₄(SiO₄)₃.

In one embodiment, the temperature for the firing may be in the range between about 300° C. to about 1000° C., or about 300° C. to about 525° C., or about 300° C. to about 650° C., or about 650° C. to about 1000° C. The firing may be conducted using any suitable heat source. In an embodiment, the firing is accomplished by passing the substrate bearing the printed composition pattern through a belt furnace at high transport rates, for example between about 100 to about 700 cm per minute, with resulting hold-up times between about 0.05 to about 5 minutes. Multiple temperature zones may be used to control the desired thermal profile, and the number of zones may vary, for example, between 3 to 11 zones. The temperature of a firing operation conducted using a belt furnace is conventionally specified by the furnace setpoint in the hottest zone of the furnace, but it is known that the peak temperature attained by the passing substrate in such a process is somewhat lower than the highest setpoint. Other batch and continuous rapid-fire furnace designs known to one of skill in the art are also contemplated.

### Method of Making a Semiconductor Device

An embodiment relates to methods of making a semiconductor device that includes a conductive structure formed with the present composition. In an embodiment, the semiconductor device may be used in a solar cell device. The semiconductor device may include a front-side electrode, wherein, prior to firing, the front-side (illuminated-side) electrode may include composition(s) described herein. In some embodiments, the substrate includes an insulating film or layer, which may be either formed specifically or naturally occurring.

In an embodiment, the method of making a semiconductor device includes the steps of: (a) providing a semiconductor substrate; (b) applying an insulating film to the semiconductor substrate; (c) applying a composition described herein to the insulating film; and (d) firing the device.

The semiconductor device may be manufactured by a method described herein from a structural element composed of a junction-bearing semiconductor substrate and a silicon nitride insulating film formed on a main surface thereof. The method of manufacture of a semiconductor device includes the steps of applying (such as coating or printing) onto the insulating film, in a predetermined shape and at a predetermined position, a composition having the ability to penetrate the insulating film, then firing so that the composition melts and passes through the insulating film, effecting electrical contact with the silicon substrate. The electrically conductive thick-film composition is a composition, as described herein, which comprises an electrically functional phase (e.g., silver or other conductive metal powder), fusible material (which may be a glass or glass powder mixture), and an organic vehicle in which the foregoing materials are dispersed. The composition optionally includes additional metal and/or metal oxide additive(s).

Exemplary semiconductor substrates useful in the methods and devices described herein are recognized by one of skill in the art, and include, but are not limited to: single-crystal silicon, multicrystalline silicon, amorphous silicon, quasi-monocrystalline silicon, ribbon silicon, and the like. The semiconductor substrate may be junction bearing. The semiconductor substrate may be doped with phosphorus and boron to form a p-n junction. Methods of doping semiconductor substrates are understood by one of skill in the art.

The semiconductor substrates may vary in size (length×width) and thickness, as recognized by one of skill in the art. In a non-limiting example, the thickness of the semiconductor substrate may be 50 to 500 microns; 100 to 300 microns; or 140 to 200 microns. In a non-limiting example, the length and width of the semiconductor substrate may both equally be 100 to 250 mm; 125 to 200 mm; or 125 to 156 mm.

Exemplary insulating films useful in the methods and devices described herein are recognized by one of skill in the art, and include, but are not limited to: silicon nitride, silicon oxide, titanium oxide, SiNₓ:H, SiC_{X}N_{Y}:H, hydrogenated amorphous silicon nitride, and silicon oxide/titanium oxide. In an embodiment the insulating film may comprise silicon nitride. The insulating film may be formed by PECVD, CVD, and/or other techniques known to one of skill in the art. In an embodiment in which the insulating film is silicon nitride, the silicon nitride film may be formed by plasma-enhanced chemical vapor deposition (PECVD), a thermal CVD process, or physical vapor deposition (PVD). In an embodiment in which the insulating film is silicon oxide, the silicon oxide film may be formed by thermal oxidation, thermal CVD, plasma CVD, or PVD. The insulating film (or layer) may also be termed the anti-reflective coating (ARC).

Compositions described herein may be applied to the ARC-coated semiconductor substrate to create a conductive structure having any desired configuration. For example, the electrode pattern used for the front side of a photovoltaic cell commonly includes a plurality of narrow grid lines or fingers connected to one or more bus bars, thereby providing electrical contact with the emitter. In an embodiment, the width of the lines of the conductive fingers may be 20 to 200 μm; 40 to 150 μm; or 60 to 100 μm. In an embodiment, the thickness of the lines of the conductive fingers may be 5 to 50 μm; 10 to 35 μm; or 15 to 30 μm. Such a pattern permits the generated current to be extracted without undue resistive loss, while minimizing the area of the front side obscured by the metallization, which reduces the amount of incoming light energy that can be converted to electrical energy. Ideally, the features of the electrode pattern should be well defined, with a preselected thickness and shape, and have high electrical conductivity and low contact resistance with the underlying structure.

A composition thus applied on an ARC-coated semiconductor substrate may be dried as recognized by one of skill in the art, for example, for 0.5 to 30 minutes, and then fired. In an embodiment, volatile solvents and organics may be removed during the drying process. Firing conditions will be recognized by one of skill in the art. In exemplary, non-limiting, firing conditions the silicon wafer substrate is heated to maximum temperature of between 600 and 900° C. for the duration of 1 second to 2 minutes. In an embodiment, the maximum silicon wafer temperature reached during firing ranges from 650 to 800° C. for the duration of 1 to 10 seconds. In a further embodiment, the electrode formed from the composition may be fired in an atmosphere composed of a mixed gas of oxygen and nitrogen. This firing process removes the organic vehicle and sinters the fusible material with the Ag powder in the conductive thick-film composition. In a further embodiment, the electrode formed from the conductive thick-film composition(s) may be fired above the organic vehicle removal temperature in an inert atmosphere not containing oxygen. This firing process sinters or melts base metal conductive materials such as copper in the composition.

In some implementations of the present process, the composition is applied over any insulating layer present on the substrate, whether specifically applied or naturally occurring. The composition's fusible material and any additive present may act in concert to combine with, dissolve, or otherwise penetrate some or all of the thickness of any insulating layer material during firing. Ideally, the firing results both in good electrical contact between the composition and the underlying semiconductor and in a secure attachment of the conductive metal structure to the substrate being formed over substantially all the area of the substrate covered by the conductive element. In an embodiment, the conductive metal is separated from the silicon by a nano-scale glass layer (typically about 5 nm or less) through which the photoelectrons tunnel. In another embodiment, contact is made between the conductive metal and the silicon by a combination of direct metal-to-silicon contact and tunneling through thin glass layers.

In a further embodiment, prior to firing, other conductive and device enhancing materials are applied to the opposite type region of the semiconductor device and co-fired or sequentially fired with the composition described herein. The opposite type region of the device is on the opposite side of the device. The materials serve as electrical contacts, passivating layers, and solderable tabbing areas.

In an embodiment, the opposite type region may be on the non-illuminated (back) side of the device. In an aspect of this embodiment, the back-side conductive material may contain aluminum. Exemplary back-side aluminum-containing compositions and methods of applying are described, for example, in US 2006/0272700, which is hereby incorporated herein by reference.

In a further aspect, the solderable tabbing material may contain aluminum and silver. Exemplary tabbing compositions containing aluminum and silver are described, for example in US 2006/0231803, which is hereby incorporated herein by reference.

In a further embodiment the materials applied to the opposite type region of the device are adjacent to the materials described herein due to the p and n region being formed side by side. Such devices place all metal contact materials on the non-illuminated (back) side of the device to maximize incident light on the illuminated (front) side.

An embodiment of the invention relates to a semiconductor device manufactured using the methods described herein. Additional substrates, devices, methods of manufacture, and the like, which may be utilized with the composition described herein, are provided in US Patent Application Publication Numbers US 2006/0231801, US 2006/0231804, and US 2006/0231800, which are hereby incorporated herein in their entireties for all purposes by reference thereto.

### EXAMPLES

The operation and effects of certain embodiments of the present invention may be more fully appreciated from a series of examples (Examples 1-23), as described below. The embodiments on which these examples are based are representative only, and the selection of those embodiments to illustrate aspects of the invention does not indicate that materials, components, reactants, conditions, techniques and/or configurations not described in the examples are not suitable for use herein, or that subject matter not described in the examples is excluded from the scope of the appended claims and equivalents thereof.

### Examples 1-20

### Glass Property Measurement

The frit compositions outlined in Tables I & II are characterized to determine density, softening point, TMA shrinkage, diaphaneity, and crystallinity. Density values calculated using the Archimedes method, known to those skilled in the art, using the measured mass of a cast specimen of glass first dry and then suspended in deionized water are shown for some glass compositions in Table III.

### Paste Preparation

Paste preparations, in general, were prepared using the following procedure: The appropriate amount of solvent(s), binder(s), thixotrope(s), and surfactant(s) were weighed and mixed in a mixing can for 15 minutes, then frits described herein, and optionally additives, were added and mixed for another 15 minutes. Since Ag is the major part of the solids, it was added incrementally to ensure better wetting. After being mixed well, the paste was repeatedly passed through a 3-roll mill at progressively increasing pressures from 0 to 300 psi. The gap of the rolls was set to 1 mil. The degree of dispersion was measured using commercial fineness of grind (FOG) gages (Precision Gage and Tool, Dayton, Ohio), in accordance with ASTM Standard Test Method D 1210-05, which is promulgated by ASTM International, West Conshohocken, Pa., and is incorporated herein by reference. In an embodiment, the FOG value for the present paste may be equal to or less than about 20/10, meaning that the size of the largest particle detected is 20 μm and the median size is 10 μm.

The paste examples of Table IV were made using the procedure described above for making the paste compositions listed in the table according to the following details. Tested pastes contained 79 to 81% silver powder. Silver type 1 had a narrow particle size distribution. Silver type 2 had a wide particle size distribution. Pastes containing ZnO contained 3.5 to 6 wt. % ZnO and 2 to 3 wt. % glass frit. Paste examples that did not contain ZnO contained 5 wt. % glass frit.

Photovoltaic cell test samples were made using both the present pastes and a commercially available control paste. The pastes were applied to 1.1″×1.1″ (28 mm×28 mm) cut cells, and efficiency and fill factor were measured for each sample. For each paste, the mean values of the efficiency and fill factor for 5 samples are shown as relative values normalized to the mean values for the cells made with the control paste.

The samples were prepared by screen printing using an ETP model L555 printer set with a squeegee speed of 250 mm/sec. The screen used had a pattern of 11 finger lines with a 100 μm opening and 1 bus bar with a 1.5 mm opening on a 10 μm emulsion in a screen with 280 mesh and 23 μm wires. The substrates used were 1.1 inch square sections cut with a dicing saw from multi-crystalline cells (acid textured; 60Ω/□ emitter coated with PECVD SiN_{X}:H ARC). A commercially available Al paste, DuPont PV381, was printed on the non-illuminated (back) side of the device. The devices with the printed patterns on both sides were then dried for 10 minutes in a drying oven with a 150° C. peak temperature. The substrates were then fired sun-side up with a RTC PV-614 6-zone IR furnace using a 4,572 mm/min belt speed and with the temperature controlled at a preselected setpoint. Firing runs were made with a series of setpoints chosen as 550, 600, 650, 700, 800, and 860° C. The actual temperature attained by the parts during their passage through the furnace's hot zone was measured. The measured peak temperature of each part was approximately 760° C. and each part was above 650° C. for a total time of 4 seconds. The fully processed samples were then tested for PV performance using a calibrated Telecom STV ST-1000 tester.

### Test Procedure-Efficiency

The solar cells built according to the method described herein were tested for conversion efficiency. An exemplary method of testing efficiency is provided below.

The solar cells built according to the method described herein were placed in a commercial I-V tester for measuring efficiencies (Model ST-1000, Telecom STV Co., Moscow, Russia). The Xe arc lamp in the I-V tester simulated sunlight with a known intensity and irradiated the front surface of the cell. The tester used a four-contact method to measure current (I) and voltage (V) at approximately 400 load resistance settings to determine the cell's I-V curve. Both fill factor (FF) and efficiency (Eff) were calculated from the I-V curve.

Paste efficiency and fill factor values were normalized to corresponding values obtained with cells contacted with industry-standard pastes which were fired at the same firing cycle.

The above efficiency test is exemplary. Other equipment and procedures for testing efficiencies will be recognized by one of ordinary skill in the art.

TABLE I
Glass Compositions Described on an Oxide and Fluoride Salt Weight Percent Basis

| | | | | | | | | | | | | | | | | | Bi₂O₃ + |
|---|---|---|---|---|---|---|---|---|---|---|---|---|---|---|---|---|---|
| frit | SiO₂ | Al₂O₃ | ZrO₂ | B₂O₃ | ZnO | CuO | Na₂O | Li₂O | Bi₂O₃ | P₂O₅ | NaF | TiO₂ | K₂O | LiF | BiF₃ | KF | BiF₃ |
| 1 | 21.92 | 0.28 | 4.81 | 3.84 | | | 1.64 | 1.50 | 64.00 | | | 2.01 | | | | | 64 |
| 2 | 21.46 | 0.27 | 4.71 | 3.76 | | | | | 61.01 | | 2.18 | 1.97 | | 2.55 | 2.09 | | 63.10 |
| 3 | 20.71 | 0.26 | 4.54 | 3.63 | | | | | 46.11 | | 2.10 | 1.90 | | 2.46 | 18.28 | | 64.39 |
| 4 | 17.31 | 0.52 | | 8.06 | | 2.62 | | 1.84 | 50.34 | | | 6.17 | | | 13.14 | | 63.48 |
| 5 | 25.02 | 4.20 | | 8.01 | | | | 0.80 | 50.90 | | | 3.27 | | | 7.80 | | 58.70 |
| 6 | 10.70 | 3.79 | 0.99 | | | | | | 76.58 | | | | | | 7.93 | | 84.52 |
| 7 | 11.12 | 3.94 | 1.03 | | | 2.04 | | | 73.93 | | | | | | 7.93 | | 81.86 |
| 8 | 8.56 | 5.43 | 0.79 | | | | 4.12 | | 58.87 | 11.79 | 1.88 | | 1.56 | | 6.35 | 0.65 | 65.21 |
| 9 | 11.79 | 2.71 | 1.51 | 0 | 19.96 | 0 | 0 | 0 | 41.58 | 3.48 | 0 | 0 | 0 | 0 | 17.40 | 0 | 58.98 |
| 10 | 15.48 | 2.49 | 1.80 | 1.53 | 12.70 | | | 1.76 | 47.74 | 1.04 | | | 0.46 | 0.78 | 12.46 | 1.76 | 60.20 |
| 11 | 20.10 | 0.26 | 4.41 | 3.52 | | | | | | | 1.50 | 1.84 | | 1.38 | 66.99 | | 66.99 |
| 12 | 21.54 | 0.37 | | 7.31 | | | | | 57.49 | | | 5.72 | | | 7.57 | | 65.06 |
| 13 | 10.55 | 1.95 | 1.14 | | | | | | 78.71 | 2.71 | | | | | 4.93 | | 83.64 |
| 14 | 10.49 | 1.94 | 1.14 | | | | | | 73.94 | 2.70 | | | | | 9.80 | | 83.74 |
| 15 | 18.09 | 2.74 | 1.99 | 1.68 | 10.97 | | | 2.28 | 41.21 | 3.43 | | | 0.59 | 1.02 | 13.72 | 2.27 | 54.93 |
| 16 | 25.34 | 1.00 | 3.78 | 2.85 | | | | | 55.64 | | 1.27 | 1.64 | | 2.14 | 6.34 | | 61.98 |
| 17 | 15.24 | 2.45 | 1.78 | | 12.50 | | | 1.74 | 46.99 | 4.09 | | | 0.45 | 0.77 | 12.26 | 1.73 | 59.26 |
| 18 | 22.74 | 0.29 | 4.99 | 3.98 | | | | | 12.94 | | 2.31 | 2.09 | | 2.70 | 47.96 | | 60.90 |
| 19 | 17.10 | 2.75 | 1.99 | | 11.00 | | | 2.76 | 41.35 | 4.59 | | | 0.72 | 1.23 | 13.77 | 2.75 | 55.11 |
| 20 | 15.58 | 2.64 | 1.92 | | 15.19 | | | 2.49 | 41.07 | 1.84 | 0.44 | | | 1.13 | 15.17 | 2.53 | 56.24 |

TABLE II
Glass Compositions Described on an
Elemental Weight Percent Basis

| frit | Si | Al | Zr | B | Zn | Cu | Ti | P | F | O | Bi | Li | Na | K |
|---|---|---|---|---|---|---|---|---|---|---|---|---|---|---|
| 1 | 10.25 | 0.15 | 3.56 | 1.19 | | | 1.21 | | | 24.33 | 57.41 | 0.70 | 1.22 | |
| 2 | 10.03 | 0.15 | 3.49 | 1.17 | | | 1.18 | | 3.30 | 22.45 | 56.37 | 0.68 | 1.19 | |
| 3 | 9.68 | 0.14 | 3.36 | 1.13 | | | 1.14 | | 6.67 | 20.35 | 55.72 | 0.66 | 1.15 | |
| 4 | 8.09 | 0.28 | | 2.50 | | 2.09 | 3.70 | | 2.81 | 24.19 | 55.48 | 0.86 | | |
| 5 | 11.69 | 2.22 | | 2.49 | | | 1.96 | | 1.67 | 27.81 | 51.79 | 0.37 | | |
| 6 | 5.00 | 2.01 | 0.74 | | | | | | 1.70 | 15.63 | 74.93 | | | |
| 7 | 5.20 | 2.09 | 0.77 | | | 1.63 | | | 1.70 | 16.07 | 72.54 | | | |
| 8 | 4.00 | 2.88 | 0.59 | | | | | 5.14 | 2.42 | 21.36 | 57.79 | | 4.08 | 1.74 |
| 9 | 5.60 | 1.46 | 1.14 | | 16.29 | | | 1.54 | 3.79 | 18.41 | 51.78 | | | |
| 10 | 7.23 | 1.32 | 1.34 | 0.47 | 10.21 | | | 0.45 | 3.82 | 19.96 | 52.61 | 1.03 | | 1.56 |
| 11 | 9.39 | 0.14 | 3.26 | 1.09 | | | 1.10 | | 16.04 | 15.14 | 52.64 | 0.37 | 0.82 | |
| 12 | 10.07 | 0.20 | | 2.27 | | | 3.43 | | 1.62 | 24.90 | 57.52 | | | |
| 13 | 4.93 | 1.03 | 0.85 | | | | | 1.18 | 1.06 | 16.47 | 74.48 | | | |
| 14 | 4.90 | 1.03 | 0.84 | | | | | 1.18 | 2.10 | 15.93 | 74.03 | | | |
| 15 | 8.46 | 1.45 | 1.47 | 0.52 | 8.81 | | | 1.50 | 4.43 | 22.26 | 47.75 | 1.33 | | 2.02 |
| 16 | 11.85 | 0.53 | 2.80 | 0.88 | | | 0.98 | | 3.50 | 23.30 | 54.89 | 0.57 | 0.69 | |
| 17 | 7.12 | 1.30 | 1.31 | | 10.05 | | | 1.79 | 3.76 | 20.34 | 51.79 | 1.01 | | 1.54 |
| 18 | 10.63 | 0.15 | 3.69 | 1.24 | | | 1.25 | | 13.30 | 18.46 | 49.29 | 0.72 | 1.26 | |
| 19 | 7.99 | 1.45 | 1.48 | | 8.84 | | | 2.00 | 4.75 | 21.53 | 47.90 | 1.61 | | 2.45 |
| 20 | 7.28 | 1.40 | 1.42 | | 12.20 | | | 0.80 | 5.10 | 19.63 | 48.76 | 1.46 | 0.24 | 1.70 |

TABLE III
Physical Properties of Glass Compositions

| | Density |
|---|---|
| frit | g/cc |
| 1 | 5.00 |
| 2 | 4.94 |
| 3 | 4.93 |
| 4 | 4.84 |
| 5 | 4.26 |
| 6 | 6.60 |
| 7 | 6.48 |
| 8 | 5.03 |
| 9 | 5.64 |
| 10 | 5.13 |
| 11 | 5.13 |
| 12 | 4.91 |
| 13 | 6.72 |
| 14 | 6.84 |
| 15 | 4.65 |
| 16 | 4.62 |
| 17 | 5.17 |
| 18 | 4.74 |
| 19 | 4.23 |
| 20 | 4.93 |

TABLE IV
Electrical Properties of Photovoltaic Cells Fabricated with
Electrodes Formed with Silver Pastes with and without ZnO
Additive

| | | | |
|---|---|---|---|
| | | Efficiency | Fill Factor |
| Ag | ZnO | (%) | (%) |

| | | | |
|---|---|---|---|
| frit | Type | Present | Normalized to Control |

| | | | | |
|---|---|---|---|---|
| 1 | 1 | Yes | 98.6 | 100.4 |
| 2 | 1 | Yes | 97.6 | 101.1 |
| 3 | 1 | Yes | 101.1 | 101.3 |
| 4 | 2 | Yes | 96.7 | 97.3 |
| 5 | 1 | Yes | 92.5 | 92.2 |
| 6 | 1 | Yes | 87.5 | 87.2 |
| 7 | 1 | Yes | 87.5 | 85.9 |
| 8 | 1 | Yes | 86.8 | 83.2 |
| 9 | 1 | Yes | 98.9 | 99.1 |
| 10 | 1 | Yes | 98.2 | 96.6 |
| 15 | 1 | Yes | 95.0 | 93.6 |
| 16 | 1 | Yes | 98.9 | 97.3 |
| 19 | 1 | Yes | 105.7 | 102.9 |
| 20 | 1 | Yes | 99.8 | 96.6 |
| 2 | 1 | No | 18.6 | 37.1 |
| 6 | 1 | No | 73.6 | 72.9 |
| 7 | 1 | No | 84.3 | 75.6 |
| 8 | 1 | No | 53.6 | 53.1 |
| 9 | 1 | No | 85.7 | 84.6 |
| 10 | 1 | No | 100.7 | 98.3 |
| 15 | 1 | No | 70.1 | 69.5 |
| 16 | 1 | No | 5.7 | 3.5 |
| 19 | 1 | No | 64.8 | 65.8 |
| 20 | 1 | No | 50.1 | 50.9 |
| Control | 2 | Yes | 100.0 | 100.0 |

### Examples 21-43

### Fusible Material and Paste Preparation

Frits for Examples 21-43 were prepared with the compositions as listed in Table V below. These frits were then formulated into compositions suitable for screen printing using the same procedure as employed for Examples 1-20 above. Silver powder (spherical, with a median particle size of 2 μm) was used. The amount of frit and Ag powder used for each, based on wt. % of the total composition, is set forth in Table VI. The balance of each composition was an organic vehicle. The viscosity of each paste was adjusted after three-roll milling to a screen-printable range (˜200-400 Pa-s) by the addition of solvent, if necessary. Viscosities were measured using a Brookfield viscometer (Brookfield, Inc., Middleboro, Mass.) with a #14 spindle and a #6 cup. The values in Table VI were recorded after 3 minutes at 10 RPM.

Photovoltaic cells in accordance with an aspect of the invention were made using the compositions of Examples 21-43 to form the front-side electrodes. For convenience, the fabrication and electrical testing were carried out on 28 mm×28 mm “cut down” wafers prepared by dicing full-size (156 mm×156 mm) wafers using a diamond wafering saw. The test wafers (Deutsche Cell, 65 ohms per square, ˜180 μm thick) were screen printed using an AMI-Presco (AMI, North Branch, N.J.) MSP-485 screen printer, first to form a full ground plane back-side conductor using a conventional Al-containing paste, Solamet® PV381 (available commercially from DuPont, Wilmington, Del.), and thereafter to form a bus bar and eleven conductor lines at a 0.254 cm pitch on the front surface using the various exemplary compositions of Examples 21-43.

After printing and drying, cells were fired in a BTU rapid thermal processing, multi-zone belt furnace (BTU International, North Billerica, Mass.). The firing temperatures reported for Examples 21-43 were the furnace set-point temperatures for the hottest furnace zone. These temperatures were found to be approximately 150° C. greater than the wafer temperature actually attained during the cells' passage through the furnace. After firing, the median conductor line width was 120 μm and the mean line height was 15 μm. The median line resistivity was 3.0 μΩ-cm.

### Photovoltaic Cell Testing

The electrical properties of photovoltaic cells fabricated using the compositions of Examples 21-43 were measured using the same protocol as set forth above for Examples 1-20, using an ST-1000 IV tester (Telecom STV Co., Moscow, Russia) at 25° C.±1.0° C. Fill factor (FF), series resistance (Ra), and efficiency (Eff) were calculated from the I-V curve for each cell. Means and medians of these quantities were calculated for the five cells of each test condition. Performance of “cut-down” 28 mm×28 mm cells is known to be impacted by edge effects which reduce the overall photovoltaic cell fill factor (FF) by ˜5% from what would be obtained with full-size wafers. Data shown in Table VI indicate the highest measured mean efficiency for the five cells of each test group, and the firing temperature at which each value was obtained.

The data of Table VI demonstrate that compositions that are lead-free and zinc-free can be used to manufacture photocells having excellent electrical properties, including high efficiency.

TABLE V
Glass Compositions Described on an Oxide and Fluoride Salt Weight Percent Basis

| Example | Bi₂O₃ | Li₂O | Li₃PO₄ | Na₂O | SiO₂ | BiF₃ | B₂O₃ | Al₂O₃ | Ga₂O₃ | ZrO₂ | TiO₂ | P₂O₅ |
|---|---|---|---|---|---|---|---|---|---|---|---|---|
| 21 | 60.72 | 1.65 | — | 1.78 | 24.13 | 11.72 | — | — | — | — | — | — |
| 22 | 79.00 | 1.99 | — | 2.83 | 13.13 | — | 3.04 | — | — | — | — | — |
| 23 | 67.47 | 1.97 | — | 2.80 | 12.98 | 11.77 | 3.00 | — | — | — | — | — |
| 24 | 76.68 | 2.02 | — | 2.87 | 6.65 | 6.88 | 4.90 | — | — | — | — | — |
| 25 | 78.06 | 1.76 | — | 2.43 | 11.77 | 4.62 | 1.37 | — | — | — | — | — |
| 26 | 74.18 | 1.26 | — | 2.61 | 10.09 | 4.65 | 2.93 | 4.27 | — | — | — | — |
| 27 | 77.89 | — | 2.89 | 2.32 | 1.79 | 4.71 | 3.90 | 2.29 | 4.20 | — | — | — |
| 28 | 79.64 | — | 2.68 | — | 3.35 | 4.67 | 3.62 | 2.13 | 3.91 | — | — | — |
| 29 | 73.50 | 1.42 | — | 1.48 | 18.10 | 4.69 | — | 0.81 | — | — | — | — |
| 30 | 72.66 | 1.40 | — | 1.46 | 17.90 | 4.63 | — | — | — | 1.94 | — | — |
| 31 | 86.19 | 1.52 | — | — | 4.06 | 2.34 | 3.53 | 0.68 | — | 1.67 | — | — |
| 32 | 86.11 | 0.50 | — | 1.02 | 5.88 | 2.43 | 3.40 | 0.66 | — | — | — | — |
| 33 | 83.61 | 1.08 | — | 2.24 | 4.35 | 2.42 | 3.77 | 0.74 | — | 1.79 | — | — |
| 34 | 79.53 | 1.13 | — | 2.10 | 1.82 | 3.51 | 4.99 | 1.54 | 2.81 | 1.91 | 0.67 | — |
| 35 | 86.33 | — | — | — | 6.72 | — | 2.96 | 3.99 | — | — | — | — |
| 36 | 87.30 | — | — | — | 6.79 | — | 1.91 | 4.00 | — | — | — | — |
| 37 | 81.66 | — | — | — | 6.35 | — | 2.97 | 4.00 | — | — | — | 5.01 |
| 38 | 82.73 | — | — | — | 6.44 | — | 2.84 | 8.00 | — | — | — | — |
| 39 | 84.08 | — | — | — | 6.54 | — | 2.88 | 6.50 | — | — | — | — |
| 40 | 80.92 | — | — | — | 6.30 | — | 2.78 | 10.00 | — | — | — | — |
| 41 | 78.68 | — | — | — | 6.12 | — | 2.70 | 12.50 | — | — | — | — |
| 42 | 76.43 | — | — | — | 5.95 | — | 2.62 | 15.00 | — | — | — | — |
| 43 | 79.68 | 0.57 | — | 1.19 | 3.68 | 2.43 | 3.41 | 9.03 | — | — | — | — |

TABLE VI
Electrical Properties of Photovoltaic Cells Fabricated with Electrodes
Formed with Silver Pastes that Are Zinc and Lead Free

| | | | | Optimal | | |
|---|---|---|---|---|---|---|
| | | | | Setpoint | Mean | Median |
| | Ag | Frit | Viscosity | Temp. | Efficiency | Efficiency |
| Example | (%) | (%) | (Pa-s) | (° C.) | (%) | (%) |
| 21 | 84 | 4 | 256 | 950 | 14.91 | 14.84 |
| 22 | 83 | 5 | 388 | 900 | 14.87 | 15.07 |
| 23 | 85 | 3 | 371 | 930 | 15.24 | 15.17 |
| 24 | 85 | 3 | 480 | 910 | 14.81 | 14.84 |
| 25 | 85 | 3 | 326 | 920 | 15.38 | 15.39 |
| 26 | 84 | 4 | 319 | 930 | 15.47 | 15.42 |
| 27 | 85 | 3 | 302 | 930 | 15.39 | 15.36 |
| 28 | 84 | 4 | 286 | 920 | 15.20 | 15.19 |
| 29 | 84 | 4 | 397 | 940 | 15.45 | 15.41 |
| 30 | 84 | 4 | 340 | 930 | 15.26 | 15.38 |
| 31 | 85 | 3 | 292 | 930 | 14.95 | 14.93 |
| 32 | 84 | 4 | 276 | 910 | 15.47 | 15.55 |
| 33 | 85 | 3 | 289 | 940 | 15.11 | 15.18 |
| 34 | 85 | 3 | 302 | 930 | 15.01 | 15.01 |
| 35 | 86 | 2 | 285 | 960 | 14.63 | 15.58 |
| 36 | 86 | 2 | 290 | 960 | 14.77 | 14.68 |
| 37 | 86 | 2 | 300 | 940 | 14.99 | 15.56 |
| 38 | 86 | 2 | 190 | 945 | 14.55 | 14.62 |
| 39 | 86 | 2 | 250 | 925 | 15.00 | 15.08 |
| 40 | 86 | 2 | 250 | 955 | 15.31 | 15.33 |
| 41 | 86 | 2 | 270 | 955 | 14.99 | 15.16 |
| 42 | 86 | 2 | 292 | 940 | 15.57 | 15.67 |
| 43 | 83 | 5 | 294 | 920 | 15.48 | 15.49 |

Having thus described the invention in rather full detail, it will be understood that this detail need not be strictly adhered to but that further changes and modifications may suggest themselves to one skilled in the art, all falling within the scope of the invention as defined by the subjoined claims.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

In this specification, unless explicitly stated otherwise or indicated to the contrary by the context of usage,

(a) amounts, sizes, ranges, formulations, parameters, and other quantities and characteristics recited herein, particularly when modified by the term “about”, may but need not be exact, and may also be approximate and/or larger or smaller (as desired) than stated, reflecting tolerances, conversion factors, rounding off, measurement error, and the like, as well as the inclusion within a stated value of those values outside it that have, within the context of this invention, functional and/or operable equivalence to the stated value; and

(b) all numerical quantities of parts, percentage, or ratio are given as parts, percentage, or ratio by weight; the stated parts, percentage, or ratio by weight may or may not add up to 100.

What is claimed is:

1. A composition comprising:
(a) a source of electrically conductive metal;
(b) a fusible material comprising:
60-90 wt. % Bi₂O₃,
0-15 wt. % Al₂O₃,
1-26 wt. % SiO₂, and
0-7 wt. % B₂O₃,
wherein the weight percentages are based on the total fusible material, and wherein some or all of at least one of the oxides is optionally replaced by a fluoride of the same cation in an amount such that the fusible material comprises at most 5 wt. % of fluorine, based on the total fusible material; and
(c) an organic vehicle, and
wherein the composition is lead-free and zinc-free.

2. The composition of claim 1, wherein the fusible material comprises:
60-90 wt. % Bi₂O₃,
0.5-12.5 wt. % Al₂O₃,
2-19 wt. % SiO₂, and
0.5-6 wt. % B₂O₃.

3. The composition of claim 1, wherein the fusible material comprises:
70-90 wt. % Bi₂O₃,
0.5-10 wt. % Al₂O₃,
2-15 wt. % SiO₂, and
1-5 wt. % B₂O₃.

4. The composition of claim 1, wherein the fusible material further comprises at least one of:
0-5 wt. % P₂O₅,
0-5 wt. % Li₂O,
0-5 wt. % Na₂O,
0-5 wt. % K₂O,
0-5 wt. % Ga₂O₃,
0-2 wt. % TiO₂,
0-2 wt. % ZrO₂,
0-2 wt. % NbO₂,
0-2 wt. % Ta₂O₅,
0-2 wt. % HfO₂,
0-2 wt. % Y₂O₃, or
0-2 wt. % of an oxide of a lanthanide group element.

5. The composition of claim 4, wherein the fusible material comprises at least one of:
0-5 wt. % P₂O₅,
0-5 wt. % Li₂O,
0-5 wt. % Na₂O,
0-5 wt. % Ga₂O₃,
0-2 wt. % TiO₂, or
0-2 wt. % ZrO₂.

6. The composition of claim 1, wherein the fusible material comprises 0-2 wt. % Li₂O, 0-3.5 wt. % Na₂O, and 0.25-4 wt. % F, with the proviso that the total amount of Li₂O and Na₂O present is at least 0.5 wt. %.

7. The composition of claim 1, further comprising a discrete material selected from one or more of the following: (a) a metal wherein said metal is selected from Bi, Gd, Ce, Zr, Ti, Mn, Sn, Ru, Co, Fe, Cu, and Cr; (b) a metal oxide of one or more of the metals selected from Bi, Gd, Ce, Zr, Ti, Mn, Sn, Ru, Co, Fe, Cu and Cr; (c) any compounds that can generate the metal oxides of (b) upon firing; and (d) mixtures thereof.

8. The composition of claim 1, wherein the fusible material consists essentially of:
50-90 wt. % Bi₂O₃,
0-15 wt. % Al₂O₃,
1-26 wt. % SiO₂, and
0-7 wt. % B₂O₃,
and optionally, one or more of
0-5 wt. % P₂O₅,
0-5 wt. % Li₂O,
0-5 wt. % Na₂O,
0-5 wt. % K₂O,
0-5 wt. % Ga₂O₃,
0-2 wt. % TiO₂,
0-2 wt. % ZrO₂,
0-2 wt. % NbO₂,
0-2 wt. % Ta₂O₅,
0-2 wt. % Hf0₂,
0-2 wt. % Y₂O₃, or
0-2 wt. % of an oxide of a lanthanide group element.

9. The composition of claim 1, wherein the fusible material consists essentially of:
70-90 wt. % Bi₂O₃,
0.5-10 wt. % Al₂O₃,
2-15 wt. % SiO₂, and
1-5 wt. % B₂O₃,
and optionally, one or more of
0-5 wt. % P₂O₅,
0-5 wt. % Li₂O,
0-5 wt. % Na₂O,
0-5 wt. % K₂O,
0-5 wt. % Ga₂O₃,
0-2 wt. % TiO₂,
0-2 wt. % ZrO₂,
0-2 wt. % NbO₂,
0-2 wt. % Ta₂O₅,
0-2 wt. % HfO₂,
0-2 wt. % Y₂O₃, or
0-2 wt. % of an oxide of a lanthanide group element.

10. The composition of claim 1, wherein the fusible material comprises 0.5 to 10 wt. % of the total composition.

11. The composition of claim 10, wherein the fusible material comprises 1 to 6 wt. % of the total composition.

12. The composition of claim 10, wherein the fusible material is a glass composition.

13. The composition of claim 1, wherein the source of the electrically conductive metal is an electrically conductive metal powder.

14. The composition of claim 1, wherein the electrically conductive metal comprises Ag.

15. The composition of claim 1, wherein the Ag comprises 75 to 99.5 wt. % of the solids in the composition.

16. A process for forming an electrically conductive structure on a substrate comprising:
(a) providing a substrate having a first major surface;
(b) applying a composition onto a preselected portion of the first major surface, wherein the composition comprises:
i. a source of electrically conductive metal;
ii. a fusible material comprising:
60-90 wt. % Bi₂O₃,
0-15 wt. % Al₂O₃,
1-26 wt. % SiO₂, and
0-7 wt. % B₂O₃,
wherein the weight percentages are based on the total fusible material, and wherein some or all of at least one of the oxides is optionally replaced by a fluoride of the same cation in an amount such that the fusible material comprises at most 5 wt. % of fluorine, based on the total fusible material; and
iii. an organic medium,
wherein the composition is lead-free and zinc-free; and
(c) firing the substrate and composition thereon, whereby the electrically conductive structure is formed on the substrate.

17. The process of claim 16, wherein the source of electrically conductive metal is silver powder.

18. The process of claim 16, wherein the substrate comprises an insulating layer present on at least the first major surface and the composition is applied onto the insulating layer of the first major surface, and wherein the insulating layer is at least one layer comprised of aluminum oxide, titanium oxide, silicon nitride, SiNₓ:H, silicon oxide, or silicon oxide/titanium oxide.

19. The process of claim 18, wherein the insulating layer is comprised of silicon nitride or SiNₓ:H.

20. The process of claim 18, wherein the insulating layer is penetrated and the electrically conductive metal is sintered during the firing, whereby an electrical contact is formed between the electrically conductive metal and the substrate.

21. An article comprising a substrate and an electrically conductive structure thereon, the article having been formed by the process of claim 18.

22. The article of claim 21, wherein the substrate is a silicon wafer.

23. The article of claim 21, wherein the article comprises a semiconductor device.

24. The article of claim 22, wherein the article comprises a photovoltaic cell.

25. A semiconductor device comprising an electrically conductive structure, wherein the electrically conductive structure, prior to firing, comprises the composition of claim 1.

26. A photovoltaic cell comprising the semiconductor device of claim 25.
